(19) United States
(12) Patent Application Publication
(10) Pub. No.: US 2020/0006680 A1
(43) Pub. Date: Jan. 2, 2020

(54) Display Panel and Manufacturing Method Thereof

(71) Applicant: Wuhan China Star Optoelectronics Semiconductor Display Technology Co., Ltd., Wuhan, Hubei (CN)

(72) Inventor: Hong Fang, Wuhan, Hubei (CN)

(73) Assignee: Wuhan China Star Optoelectronics Semiconductor Display Technology Co., Ltd., Wuhan, Hubei (CN)

(21) Appl. No.: 16/090,905

(22) PCT Filed: Aug. 23, 2018
(86) PCT No.: PCT/CN2018/101860

§ 371 Date: May 19, 2019

(30) Foreign Application Priority Data
Jun. 29, 2018 (CN) 201810701540.0

(51) Int. Cl. H01L 51/00; H01L 27/32; H01L 51/56

(52) U.S. Cl. CPC H01L 51/0097; H01L 27/3244; H01L 2251/5338; H01L 2227/323; H01L 51/56

(57) ABSTRACT

A display panel has a display area and a bent area. The display panel includes a flexible substrate; an etching stop layer disposed on the flexible substrate; an inorganic material functional layer disposed on the etching stop layer, each of the flexible substrate, the etching stop layer, and the inorganic material functional layer including the display area and the bent area; a planar layer disposed on the inorganic material functional layer; and an anode and a pixel defining layer formed on the planar layer successively. The bent area includes a groove disposed on the etching stop layer, the groove penetrates the inorganic material functional layer by etching and is filled with a polymer material, and the bent area and the display area are coupled with each other through a signal line.

### BACKGROUND OF INVENTION

### 1. Field of Invention

The present invention relates to displaying, and particularly to a flexible display panel and a manufacturing method thereof.

### 2. Related Art

Display screens of small-sized mobile phones in current markets show a tendency toward being full screen displays, and products with a greater screen ratio are continuously pushed out. Standards of quality of full screen products are nonstop raised. During development of full screen displays, flexible displays have more advantages because of their bendable properties.

As shown in FIG. 1, currently, in order to increase a screen ratio of flexible display screens, pad bending processes are generally adopted to directly bend a screen 91 to form a bent portion 92. The bent portion 92 bends to a back side of the screen 91 to reduce length of borders, thereby increasing a screen ratio. Pad bending processes are involved with large depth etching of inorganic film layers. However, uniformity of etching depth is difficult to control in processes. During etching processes, it is very easy to harm a surface of a polyimide (PI) substrate, resulting in PI loss and PI outgassing, thereby to reduce time periods for preventive maintenance (PM) of devices and significantly limit productivity. Furthermore, outgassing will cause performance of thin-film transistors (TFTs) to be unstable and adversely affect product yield. In the event that etching amount is insufficient, bending effect of modules would be poor, resulting in a problem that metal peeling of inorganic layers is easily to take place during bending processes.

### SUMMARY OF INVENTION

An object of the present invention is to provide a display panel adapted to flexible display devices to overcome drawbacks that during current etching processes, it is very easy to harm a surface of a polyimide (PI) substrate, resulting in PI loss and PI outgassing, thereby to adversely affect product yield and shorten lifespan of products.

To achieve the above-mentioned object, the present invention provides a display panel, including a display area and a bent area, the display panel comprising:
a flexible substrate;
an etching stop layer disposed on the flexible substrate;
an inorganic material functional layer disposed on the etching stop layer, each of the flexible substrate, the etching stop layer, and the inorganic material functional layer comprising the display area and the bent area;
a planar layer disposed on the inorganic material functional layer; and an anode and a pixel defining layer formed on the planar layer successively;
wherein the bent area comprises a groove disposed on the etching stop layer, the groove penetrates the inorganic material functional layer by etching and is filled with a polymer material, and the bent area and the display area are coupled with each other through a signal line.

In one aspect of the present invention, the etching stop layer comprises aluminum oxide, and the flexible substrate comprises a substrate and a first polyimide layer formed on the substrate.

In another aspect of the present invention, the inorganic material functional layer comprises a first barrier layer formed on the etching stop layer, a buffering layer formed on the first barrier layer, and a structural film layer formed on the buffering layer.

In another aspect of the present invention, a second polyimide layer and a second barrier layer are formed between the buffering layer and the first barrier layer, and the second polyimide layer is located between the first barrier layer and the second barrier layer.

In another aspect of the present invention, the first barrier layer is formed by a deposition of silicon oxide or silicon nitride and silicon oxide.

In another aspect of the present invention, the buffering layer is formed by a deposition of silicon oxide or silicon nitride and silicon oxide.

In another aspect of the present invention, the structural film layer comprises a polycrystalline silicon layer, a gate electrode layer, and a dielectric layer.

In another aspect of the present invention, a silicon nitride layer or a silicon oxide layer is deposited between the etching stop layer and the flexible substrate.

The present invention further provides a method of manufacturing a display panel, the display panel having a display area and a bent area, the method comprising:
providing a flexible substrate;
forming an etching stop layer on the flexible substrate;
forming an inorganic material functional layer on the etching stop layer, each of the flexible substrate, the etching stop layer, and the inorganic material functional layer comprising the display area and the bent area;
forming a planar layer, an anode and a pixel defining layer on the inorganic material functional layer; and
forming a groove at the bent area, the groove disposed on the etching stop layer and penetrating the inorganic material functional layer by etching, the groove filled with a polymer material, and the bent area and the display area coupled with each other through a signal line.

In one aspect of the present invention, the etching stop layer comprises aluminum oxide, and the flexible substrate comprises a substrate and a first polyimide layer formed on the substrate.

In another aspect of the present invention, the inorganic material functional layer comprises a first barrier layer formed on the etching stop layer, a buffering layer formed on the first barrier layer, and a structural film layer formed on the buffering layer.

In another aspect of the present invention, a second polyimide layer and a second barrier layer are formed between the buffering layer and the first barrier layer, and the second polyimide layer is located between the first barrier layer and the second barrier layer.

In another aspect of the present invention, the structural film layer comprises a polycrystalline silicon layer, a gate electrode layer, and a dielectric layer.

The present invention further provides a display panel, including a display area and a bent area, the display panel comprising:
a flexible substrate comprising a substrate and a first polyimide layer formed on the substrate;
an etching stop layer disposed on the flexible substrate;
an inorganic material functional layer disposed on the etching stop layer, the inorganic material functional layer comprising a first barrier layer formed on the etching stop layer, a buffering layer formed on the first barrier layer, a structural film layer formed on the buffering layer, a second polyimide layer and a second barrier layer both formed between the buffering layer and the first barrier layer, and the second polyimide layer located between the first barrier layer and the second barrier layer;
a planar layer disposed on the inorganic material functional layer; and
an anode and a pixel defining layer formed on the planar layer successively;
wherein the bent area comprises a groove disposed on the etching stop layer, the groove penetrates the inorganic material functional layer by etching and is filled with a polymer material, and the bent area and the display area are coupled with each other through a signal line.

In one aspect of the present invention, the etching stop layer comprises aluminum oxide.

In another aspect of the present invention, the first barrier layer is formed by a deposition of silicon oxide or silicon nitride and silicon oxide.

In another aspect of the present invention, the buffering layer is formed by a deposition of silicon oxide or silicon nitride and silicon oxide.

In another aspect of the present invention, the structural film layer comprises a polycrystalline silicon layer, a gate electrode layer, and a dielectric layer.

In another aspect of the present invention, a silicon nitride layer or a silicon oxide layer is deposited between the etching stop layer and the flexible substrate.

The present invention utilizes the etching stop layer of aluminum oxide disposed on the flexible substrate, and because aluminum oxide has a higher etching selectivity in comparison with a general inorganic film layer, such as silicon nitride and silicon oxide, and aluminum oxide has a strong bond, a highest hardness among oxides, a high chemical stability, and an excellent corrosion resistance to most acidic, alkaline, salt and molten solutions, there is no need to worry about that the polyimide layer will be etched during the etching processes, thereby resulting in PI loss and PI outgassing. The display panel of the present invention is capable of improving uniformity of etching depth of the bent area, product yield, and productivity, and thus effectively overcomes drawbacks of PI loss and shorter lifespan of products caused by traditional etching processes.

### BRIEF DESCRIPTION OF DRAWINGS

FIG. 1 is a schematic side view showing a traditional mobile phone with a full screen and a bent area.

FIG. 2 is a partially schematic cross-sectional view of a display panel in accordance with an embodiment of the present invention.

FIG. 3 is another partially schematic cross-sectional view of the display panel of the present invention.

FIG. 4 is a partially schematic cross-section view of an active display area of the display panel of the present invention.

FIG. 5 is another partially schematic cross-sectional view of the display panel of the present invention.

FIG. 6 is another partially schematic cross-sectional view of the display panel of the present invention.

FIG. 7 is a schematic view showing a groove formed on a bent area of the display panel of the present invention, wherein the groove is filled with a polymer material.

FIG. 8 is a schematic cross-sectional view of the display panel of the present invention.

FIG. 9 is a schematic expanded view of the full screen display panel of the present invention.

FIG. 10 is a flow chart of a method of manufacturing a display panel of the present invention.

FIG. 11 is a partially schematic cross-sectional view of a display area of a display panel in accordance with another embodiment of the present invention.

FIG. 12 is a partially schematic cross-sectional view of a bent area of the display panel of FIG. 11.

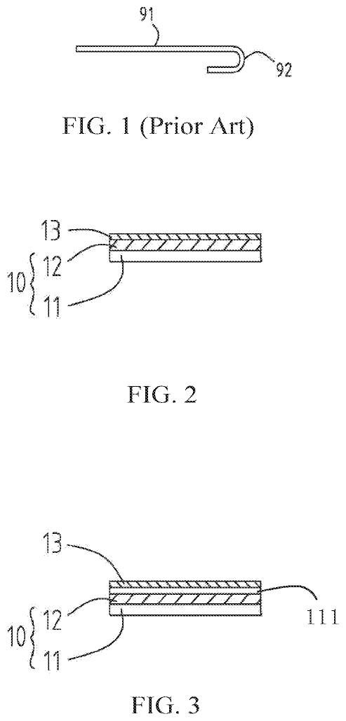

### DESCRIPTION OF PREFERRED EMBODIMENTS

As used in this specification the term “embodiment” means an instance, an example, or an illustration. In addition, for the articles in this specification and the appended claims. “a” or “an” in general can be interpreted as “one or more” unless specified otherwise or clear from context to determine the singular form.

A display panel of the present invention is an organic light emitting diode (OLED) display panel. The present invention is to realize a full screen display panel through pad bending processes to bend edge portions of a substrate to a back side of the screen display, thereby forming a bent area capable of reducing length of lower edges of the substrate and enlarging a screen ratio of the display area. In particular, an enlarged effect of the display area is much more remarkable for small-sized screen mobile phones.

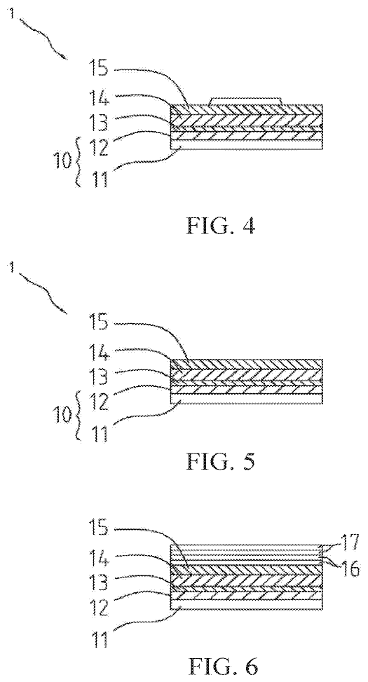

FIG. 2 is a partially schematic cross-sectional view of a display panel in accordance with an embodiment of the present invention and can also be referred to as a description of manufacturing processes. As shown in FIG. 2, a display panel 1 comprises a flexible substrate 10 comprising a substrate 11 and a first polyimide (PI) layer 12 formed on the substrate 11, wherein the first PI layer 12 has a thickness of 5-10 micrometers (um). An etching stop layer 13 is disposed on the flexible substrate 10 and comprises aluminum oxide of a thickness of 3-20 um. FIG. 3 illustrates another embodiment of the flexible substrate 10 comprising aluminum oxide, wherein a silicon nitride layer or a silicon oxide layer of 1-10 nanometers (nm) is first deposited on the first PI layer 12, and then the etching stop layer 13 of aluminum oxide is deposited on the silicon nitride layer or the silicon oxide layer to further stop etching.

FIG. 4 is a partially schematic cross-section view of a display area of the display panel of the present invention. As shown in FIG. 4, an inorganic material functional layer is disposed on the etching stop layer 13 of aluminum oxide. Each of the flexible substrate 10, the etching stop layer 13, and the inorganic material functional layer comprises the display area and the bent area. The inorganic material functional layer comprises a first barrier layer 14 formed on the etching stop layer 13, a buffering layer 15 formed on the first barrier layer 14, and a structural film layer formed on the buffering layer 15. The first barrier layer 14 has a thickness of 3000-6000 Ångström (Å) and comprises silicon oxide. In another embodiment, the first barrier layer 14 is a compound layer comprising silicon nitride and silicon oxide. The buffering layer 15 comprises silicon oxide.

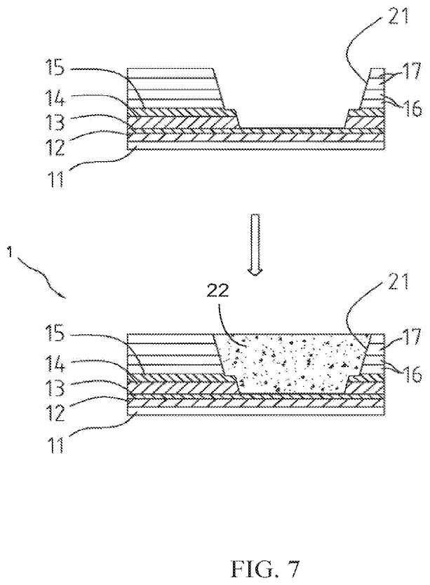

A polycrystalline active layer is formed on the buffering layer 15 through excimer-laser annealing (ELA), and is patterned by processes of exposure, drying, and stripping. FIG. 5 is another partially schematic cross-sectional view of the display panel of the present invention.

Specifically, the buffering layer 15 comprises silicon oxide of a thickness of 3000-6000 Å. In another embodiment, the buffering layer 15 is a compound layer comprising silicon nitride of a thickness of 500-800 Å and silicon oxide of a thickness of 3000-6000 Å. The buffering layer 15 functions as a buffering protection layer for the flexible substrate 10, and the first barrier layer 14 is capable of improving protection for the flexible substrate 10 and preventing water from entering a surface of the flexible substrate 10.

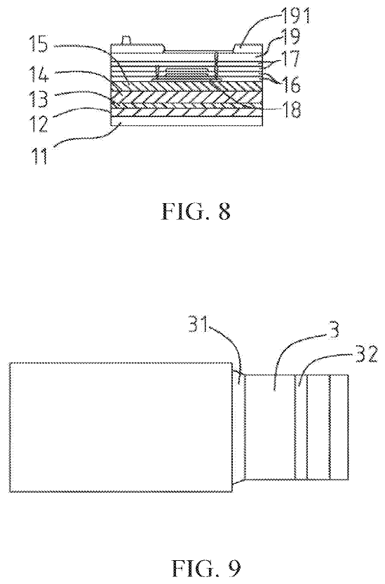

FIG. 6 is a partially schematic cross-sectional view of the display panel of the present invention. As shown in FIGS. 6 and 8, the structural film layer is formed on the buffering layer 15 of the inorganic material functional layer. The structural film layer comprises a polycrystalline silicon layer 18, a gate electrode layer 16, and a dielectric layer 17. A number of each of the gate electrode layer 16 and the dielectric layer 17 is two. One of the gate electrode layers 16 close to the buffering layer 15 is formed by a deposition of silicon oxide of 900-1500 Å. The other gate electrode layer 16 is formed by a deposition of silicon nitride of 1000-1300 Å, and the two gate electrode layers 16 are patterned. The dielectric layer 17 is formed by a deposition of silicon oxide or silicon nitride.

FIG. 8 is a schematic cross-sectional view of the display panel with respect to the display area. The polycrystalline silicon layer 18 is formed on the buffering layer 15, and the dielectric layer 17 is patterned. A first fan-out area 31 and a second fan-out area 32 of the bent area are coupled with a signal line of the display area through via hole connection. A planar layer 19, an anode and a pixel defining layer 191, and isolation columns are formed on the structural film layer, thereby to complete structure of the bent area of the display panel.

FIG. 7 is a schematic view showing a groove formed on a bent area of the display panel of the present invention. Particularly, the bent area of the present invention comprises a groove 21 formed on the etching stop layer 13, and the groove 21 penetrates the inorganic material functional layer by etching processes and is filled with a polymer material to improve bending resistance of the bent area. Specifically, the groove 21 penetrates each layer of the structural film layer, the buffering layer 15 of the inorganic material functional layer, and the first barrier layer 14. The flexible substrate 10 is protected from being etched during the etching processes because the etching stop layer 13 of aluminum oxide is deposited on the flexible substrate 10 and has higher etching selectivity.

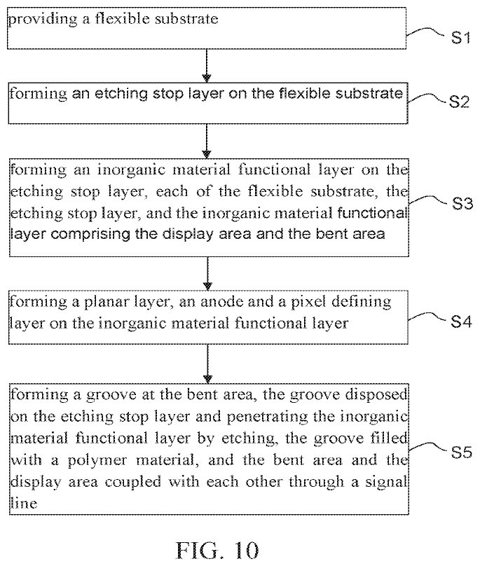

FIG. 9 is a schematic expanded view of the full screen display panel of the present invention. As shown in FIG. 9, a side edge of the active display area is a bent area 3. Opposite sides of the bent area 3 are the first fan-out area 31 and the second fan-out area 32. As described above, the first fan-out area 31 and the second fan-out area 32 of the bent area 3 are coupled with the display area via a signal line.

The present invention utilizes the etching stop layer 13 of aluminum oxide disposed on the flexible substrate 10, and because aluminum oxide has a higher etching selectivity in comparison with a general inorganic film layer, such as silicon nitride and silicon oxide, and aluminum oxide has a strong bond, a highest hardness among oxides, a high chemical stability, and an excellent corrosion resistance to most acidic, alkaline, salt and molten solutions, there is no need to worry about that the first PI layer 12 will be etched during the etching processes, thereby resulting in PI loss and PI outgassing. The display panel of the present invention is capable of improving uniformity of etching depth of the bent area, product yield, and productivity, and thus effectively overcomes drawbacks of PI loss and shorter lifespan of products caused by traditional etching processes.

As shown in FIG. 10, the present invention further provides a method of manufacturing a display panel, the display panel having a display area and a bent area. The method comprises: S1: providing a flexible substrate comprising a substrate and a polyimide layer.

S2: forming an etching stop layer of aluminum oxide on the flexible substrate by a deposition equipment. The deposition equipment can be used for carrying out physical vapor deposition with target material oxidation plating, or the etching stop layer is formed by evaporation through an atomic layer deposition equipment. Alternatively, a silicon nitride layer or a silicon oxide layer is deposited between the etching stop layer and the flexible substrate.

S3: forming an inorganic material functional layer on the etching stop layer, each of the flexible substrate, the etching stop layer, and the inorganic material functional layer comprising the display area and the bent area, wherein the inorganic material functional layer comprises a first barrier layer formed on the etching stop layer, a buffering layer formed on the first barrier layer, and a structural film layer formed on the buffering layer.

Particularly, in another embodiment of the present invention, a second polyimide layer and a second barrier layer are formed between the buffering layer and the first barrier layer, and the second polyimide layer is located between the first barrier layer and the second barrier layer, so as to form two polyimide layers.

S4: forming a planar layer, an anode and a pixel defining layer on the inorganic material functional layer.

S5: forming a groove at the bent area, the groove disposed on the etching stop layer and penetrating the inorganic material functional layer by etching, the groove filled with a polymer material, and the bent area and the display area coupled with each other through a signal line. Other structural components of the display panel manufactured by the method of the present invention are described in the above paragraphs and are not to be repeatedly depicted herein.

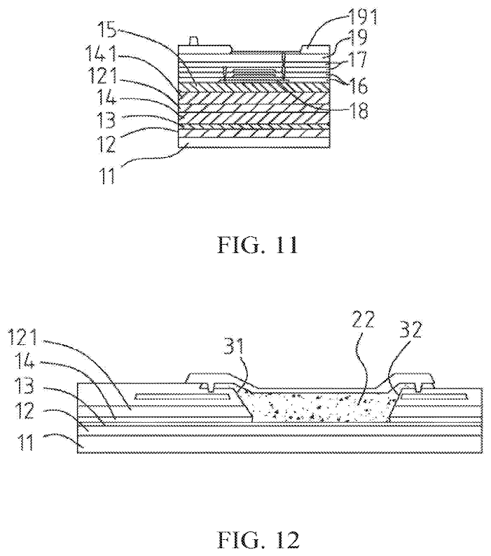

FIG. 11 is a partially schematic cross-sectional view of a display area of a display panel in accordance with another embodiment of the present invention. FIG. 12 is a partially schematic cross-sectional view of a bent area of the display panel of FIG. 11. Differences between embodiments of FIGS. 11 and 12 and the embodiments illustrated in the above paragraphs are as follows: a display panel of FIGS. 11 and 12 is provided with a second PI layer, and other structures are the same as the display panel of the above-mentioned embodiments. Furthermore, in addition to the second PI layer, a method of manufacturing a display panel of the embodiments of FIGS. 11 and 12 is the same as the method described in the above-mentioned embodiments.

Specifically, a display panel 1 of the embodiment of FIG. 11 comprises a flexible substrate 10; an etching stop layer 13 disposed on the flexible substrate 10; an inorganic material functional layer disposed on the etching stop layer 13; each of the flexible substrate 10, the etching stop layer 13, and the inorganic material functional layer comprising a display area and a bent area; a planar layer 19 disposed on the inorganic material functional layer; and an anode and a pixel defining layer 191 formed on the planar layer successively.

In this embodiment, the inorganic material functional layer comprises a first barrier layer 14 formed on the etching stop layer 13, and a second polyimide layer 121 formed on the first barrier layer 14. A second barrier layer 141 is formed on the second PI layer 121, and the buffering layer 15 is formed on the second barrier layer 141, wherein the second barrier layer 141 is made of the same material as the first barrier layer 14. In other words, the second PI layer 121 is located between the first barrier layer 14 and the second barrier layer 141 such that two PI layers 12 and 121 are provided. Furthermore, the structural film layer comprising the polycrystalline silicon layer 18, the gate electrode layer 16, and the dielectric layer 17 is disposed on the buffering layer 15.

Specifically, the etching stop layer 13 is disposed on the flexible substrate 10 and comprises aluminum oxide of a thickness of 3-20 um, the first barrier layer 14 of a thickness of 3000-6000 Å is formed on the etching stop layer 13, the second PI layer 121 of a thickness of 5-10 um is disposed on the first barrier layer 14, and the second barrier layer 141 and the buffering layer 15 are successively disposed on the second PI layer 121. By the adding of the second PI layer 121, the display panel 1 is configured with the first PI layer 12 and the second PI layer 121 separately disposed from the first PI layer 12 to improve toughness and strength of the display panel as well as better temperature tolerance.

As shown in FIG. 12, in this embodiment, the bent area comprises a groove 13 disposed on the etching stop layer 13, the groove penetrates the inorganic material functional layer by etching and is filled with a polymer material to improve bending resistance of the bent area. The bent area and the display area are coupled with each other through a signal line. Specifically, the first fan-out area 31 and the second fan-out area 32 of the bent area 3 are coupled with a signal line of the display area through via hole connection.

It is understood that the invention may be embodied in other forms within the scope of the claims. Thus the present examples and embodiments are to be considered in all respects as illustrative, and not restrictive, of the invention defined by the claim.

What is claimed is:

1. A display panel, including a display area and a bent area, the display
panel comprising:
a flexible substrate;
an etching stop layer disposed on the flexible substrate;
an inorganic material functional layer disposed on the etching stop layer, each of the flexible substrate, the etching stop layer, and the inorganic material functional layer comprising the display area and the bent area;
a planar layer disposed on the inorganic material functional layer; and
an anode and a pixel defining layer formed on the planar layer successively;
wherein the bent area comprises a groove disposed on the etching stop layer, the groove penetrates the inorganic material functional layer by etching and is filled with a polymer material, and the bent area and the display area are coupled with each other through a signal line.

2. The display panel of claim 1, wherein the etching stop layer comprises aluminum oxide, and the flexible substrate comprises a substrate and a first polyimide layer formed on the substrate.

3. The display panel of claim 1, wherein the inorganic material functional layer comprises a first barrier layer formed on the etching stop layer, a buffering layer formed on the first barrier layer, and a structural film layer formed on the buffering layer.

4. The display panel of claim 3, wherein a second polyimide layer and a second barrier layer are formed between the buffering layer and the first barrier layer, and the second polyimide layer is located between the first barrier layer and the second barrier layer.

5. The display panel of claim 3, wherein the first barrier layer is formed by a deposition of silicon oxide or silicon nitride and silicon oxide.

6. The display panel of claim 3, wherein the buffering layer is formed by a deposition of silicon oxide or silicon nitride and silicon oxide.

7. The display panel of claim 3, wherein the structural film layer comprises a polycrystalline silicon layer, a gate electrode layer, and a dielectric layer.

8. The display panel of claim 1, wherein a silicon nitride layer or a silicon oxide layer is deposited between the etching stop layer and the flexible substrate.

9. A method of manufacturing a display panel, the display panel having a display area and a bent area, the method comprising:
providing a flexible substrate;
forming an etching stop layer on the flexible substrate;
forming an inorganic material functional layer on the etching stop layer, each of the flexible substrate, the etching stop layer, and the inorganic material functional layer comprising the display area and the bent area;
forming a planar layer, an anode and a pixel defining layer on the inorganic material functional layer; and
forming a groove at the bent area, the groove disposed on the etching stop layer and penetrating the inorganic material functional layer by etching, the groove filled with a polymer material, and the bent area and the display area coupled with each other through a signal line.

10. The method of claim 9, wherein the etching stop layer comprises aluminum oxide, and the flexible substrate comprises a substrate and a first polyimide layer formed on the substrate.

11. The method of claim 9, wherein the inorganic material functional layer comprises a first barrier layer formed on the etching stop layer, a buffering layer formed on the first barrier layer, and a structural film layer formed on the buffering layer.

12. The method of claim 11, wherein a second polyimide layer and a second barrier layer are formed between the buffering layer and the first barrier layer, and the second polyimide layer is located between the first barrier layer and the second barrier layer.

13. The method of claim 11, wherein the structural film layer comprises a polycrystalline silicon layer, a gate electrode layer, and a dielectric layer.

14. A display panel, including a display area and a bent area, the display panel comprising:
a flexible substrate comprising a substrate and a first polyimide layer formed on the substrate;
an etching stop layer disposed on the flexible substrate;
an inorganic material functional layer disposed on the etching stop layer, the inorganic material functional layer comprising a first barrier layer formed on the etching stop layer, a buffering layer formed on the first barrier layer, a structural film layer formed on the buffering layer, a second polyimide layer and a second barrier layer both formed between the buffering layer and the first barrier layer, and the second polyimide layer located between the first barrier layer and the second barrier layer;
a planar layer disposed on the inorganic material functional layer; and
an anode and a pixel defining layer formed on the planar layer successively;
wherein the bent area comprises a groove disposed on the etching stop layer, the groove penetrates the inorganic material functional layer by etching and is filled with a polymer material, and the bent area and the display area are coupled with each other through a signal line.

15. The display panel of claim 14, wherein the etching stop layer comprises aluminum oxide.

16. The display panel of claim 14, wherein the first barrier layer is formed by a deposition of silicon oxide or silicon nitride and silicon oxide.

17. The display panel of claim 14, the buffering layer is formed by a deposition of silicon oxide or silicon nitride and silicon oxide.

18. The display panel of claim 14, wherein the structural film layer comprises a polycrystalline silicon layer, a gate electrode layer, and a dielectric layer.

19. The display panel of claim 14, wherein a silicon nitride layer or a silicon oxide layer is deposited between the etching stop layer and the flexible substrate.
